(19) United States
(12) Patent Application Publication
(10) Pub. No.: US 2015/0058701 A1
(43) Pub. Date: Feb. 26, 2015

(54) FLASH MEMORY CONTROLLER AND METHOD OF DATA TRANSMISSION BETWEEN FLASH MEMORIES

(71) Applicant: MEMORIGHT (WUHAN) CO., LTD., Wuhan, Hubei (CN)

(72) Inventors: Jipeng Xing, Wuhan (CN); Wenjie Huo, Wuhan (CN)

(73) Assignee: Memoright (WUHAN) Co., Ltd., Wuhan, Hubei (CN)

(21) Appl. No.: 14/354,575

(22) PCT Filed: Sep. 27, 2012
(86) PCT No.: PCT/CN2012/082131

§ 371 Date: Sep. 21, 2014

(30) Foreign Application Priority Data
Oct. 27, 2011 (CN) 201110332025.8

(51) Int. Cl. G06F 11/10; G11C 29/52

(52) U.S. Cl. CPC G06F 11/1072; G11C 29/52
USPC 714/773

(57) ABSTRACT

Provided is a flash memory controller and a method for transmitting data between flash memories. The method includes: implementing parallel processing in a manner of separating data transmission from error detection processing, and performing delayed acknowledgment on correctness of data transmitted to a target flash memory. In addition, an error detection unit performs correction processing on data in which an error occurs, and performs an update with correct data after correction and overwrites erroneous data in a buffer of the flash memory. The foregoing technical solution may make full use of bandwidth between a flash memory controller and a flash memory array, thereby enhancing data transmission efficiency; furthermore, correction processing is also hidden in the process of data transmission, and data transmission performance of the flash memory controller in the flash memory array is further enhanced; the technical solution is applicable to a controller for various storage devices in which a flash memory device is used as a storage medium.

### BACKGROUND

1. Technical Field

The present invention relates to the technologies of data storage, and more particularly to a flash memory controller for performing control on a storage device in which a flash memory device is used as a storage medium, and a method of data transmission between flash memories.

2. Related Art

In an existing solid-state drive or portable terminal, a plurality of flash memory chips is organized in an array manner and performs data exchange with a flash memory controller, so as to enhance data transmission efficiency. An organization manner of a flash memory array is shown in FIG. 1. The flash memory array is divided into a plurality of channels, and each channel is connected to the flash memory controller through an independent bus. Such an array structure can ensure transmission of data between a separate channel and a flash memory controller, and also does not affect data communication between other channels and the flash memory controller.

A multi-channel flash memory array can enhance a throughput between a flash memory device and a flash memory controller; however, interferences of various parasitic physical effects such as programming disturbances, read disturbances, and a floating gate coupling effect exist in the flash memory device. As the number of times of programming on the flash memory device increases and physical characteristics of the device attenuates, the influence of these parasitic effects grows significantly, causing an increase to errors in a flash memory. Therefore, in the process that a flash memory chip saves and transmits data, a case of data errors occurs inevitably, and these errors impairs transmission performance of the multi-channel flash memory array. When the flash memory controller needs to perform data transmission in different flash memory devices, the accumulation of data errors even causes that the flash memory controller fails to recover data from an error. Therefore, after receiving data, the flash memory controller needs to perform a correction operation on the data. If an error occurs in the data, the data has to undergo correction processing before being stored by the flash memory controller again. In such a process, the flash memory controller not only needs to buffer each piece of data, but also needs to retransmit the data by occupying an extra bandwidth resource. In the process of data transmission of the flash memory array, a relevant operation caused by a data error not only increases system resource overhead, but also reduces efficiency of data transmission between the entire flash memory array and the controller. Therefore, to reduce overhead for correction processing in a flash memory array already becomes one of the critical problems that must be solved for a flash memory device in high-speed data transmission applications. No patent application to solve the technical problem is found in searches made in existing patents.

### SUMMARY

### Technical Problem

The major technical problem that the present invention is to solve is to provide a flash memory controller and a method of data transmission between flash memories, so as to achieve that data error detection and processing operations are hidden in the process of direct data exchange; further, system resource overhead for correction processing is reduced by performing correction processing in the flash memory controller after an error is detected.

### Technical Solution

To solve the foregoing technical problem, the present invention provides a flash memory controller, which includes a transmission control module, where the transmission control module includes: a control unit, an error detection unit, and an interface unit; the control unit is connected to the error detection unit and the interface unit, respectively, and is used to generate a read/write control instruction for data transmission between flash memories, the read/write control instruction includes: a direct data transmission control instruction and a data error detection control instruction; the interface unit is further connected to a flash memory array, and is used to provide a data transmission interface to accomplish data transmission between the flash memory controller and the flash memory array; and the error detection unit is used to receive the data transmitted between the flash memories, and detect whether an error occurs in the data.

Further, the direct data transmission control instruction is used to control the data between the flash memories to be transmitted from a source flash memory to a target flash memory in the flash memory array; and the data error detection control instruction is used to control the data between the flash memories to be transmitted from the source flash memory in the flash memory array to the error detection unit through the interface unit.

Further, the interface unit is connected to the flash memory array through a data bus.

Further, the error detection unit is further used to perform correction processing on detected data in which an error occurs; and the read/write control instruction generated by the control unit further includes: a corrected data control instruction.

Further, the corrected data control instruction is used to control the error detection unit to transmit the data after correction processing to the target flash memory in the flash memory array through the interface unit.

The present invention further provides a method of data transmission between flash memories, which includes the following processing processes: reading data from a source flash memory in a flash memory array, and transmitting the data in the following two paths, respectively: one path being directly transmitting the data to a target flash memory in the flash memory array, and the other path being transmitting the data to an error detection unit through an interface unit; performing, by the error detection unit, error detection on the received data; storing, by the target flash memory, the received data in a buffer of the flash memory; and if a result of the error detection is that no error occurs in the data, writing the buffered data in a storage unit of the target flash memory.

Further, the two paths of data are transmitted through a data bus.

Further, the two paths of data are transmitted in parallel.

Further, after the transmission of the two paths of data is accomplished, the error detection unit starts to perform error detection on the received data.

Further, when the result of the error detection is that an error occurs in the data, after correction processing is performed on the data, the data is written in the storage unit of the target flash memory.

Further, the correction processing is specifically: performing, by the error detection unit, correction processing on the data, and writing the corrected data in the storage unit of the target flash memory through the interface unit.

Further, the writing the corrected data in the storage unit of the target flash memory includes the following processing processes: writing the corrected data in a buffer unit of the target flash memory through the interface unit to perform a data update, and then writing the buffered data in the storage unit of the target flash memory.

Beneficial Effect

By adopting a parallel processing mechanism in which direct data transmission is separated from error detection processing, an error detection unit may perform fast detection in the process of directly transmitting data from a source flash memory to a target flash memory in a flash memory array, and perform delayed acknowledgment on correctness of the data. The present invention makes full use of bandwidth between a flash memory controller and the flash memory array, thereby enhancing a utilization rate of data transmission.

In addition, the error detection unit directly performs correction processing on data in which an error occurs, and may transmit the data after correction processing to the target flash memory in the flash memory array through an interface unit to overwrite the erroneous data. Furthermore, such a processing mechanism also hides correction processing in the process of data transmission, thereby further enhancing data transmission performance of the flash memory controller in the flash memory array.

### BRIEF DESCRIPTION OF THE DRAWINGS

The present disclosure will become more fully understood from the detailed description given herein below for illustration only, and thus are not limitative of the present disclosure, and wherein:

FIG. 1 is a schematic view of an existing flash memory storage structure;

FIG. 2 is a flow chart of data transmission of a flash memory controller according to Embodiment 1 of the present invention;

FIG. 3 is a sequence diagram of data transmission of the flash memory controller according to Embodiment 1 of the present invention;

FIG. 4 is a flow chart of data correction of a flash memory controller according to Embodiment 2 of the present invention;

FIG. 5 is a sequence diagram of data correction of the flash memory controller according to Embodiment 2 of the present invention; and

FIG. 6 is a flow chart of a method of data transmission between flash memories according to the present invention.

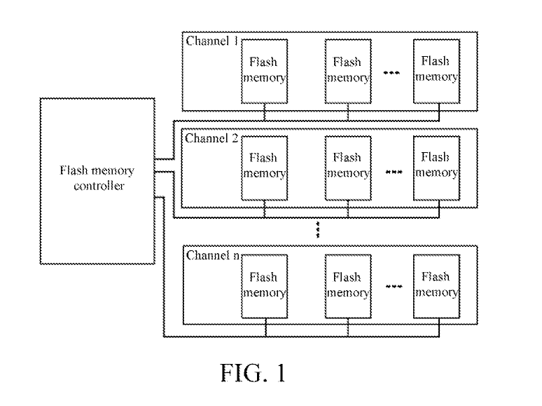

### DETAILED DESCRIPTION

The present invention is further illustrated below in detail with reference to specific implementation manners and accompanying drawings.

A major inventive concept of the present invention is to make an improvement to an existing flash memory controller. In a flash memory controller, the function of a transmission control module is mainly responsible for accomplishing data communication between the flash memory controller and a flash memory array, and therefore, a control unit, an error detection unit, and an interface unit are disposed in the transmission control module of the present invention. The control module is connected to the error detection unit and the interface unit respectively, and is responsible for instruction control and scheduling in the process of data transmission; specifically, the control module generates a read/write control instruction for data transmission between flash memories, and the read/write control instruction includes: a control instruction for controlling data transmission between different flash memories and an instruction for controlling the error detection unit to perform error detection on the data. An end of the interface unit is connected to the flash memory array through a data bus, and is responsible for accomplishing data transmission between the flash memory controller and the flash memory array. The error detection unit is responsible for perform error detection on the received data.

Embodiment 1 is a process of data transmission when no error occurs in data.

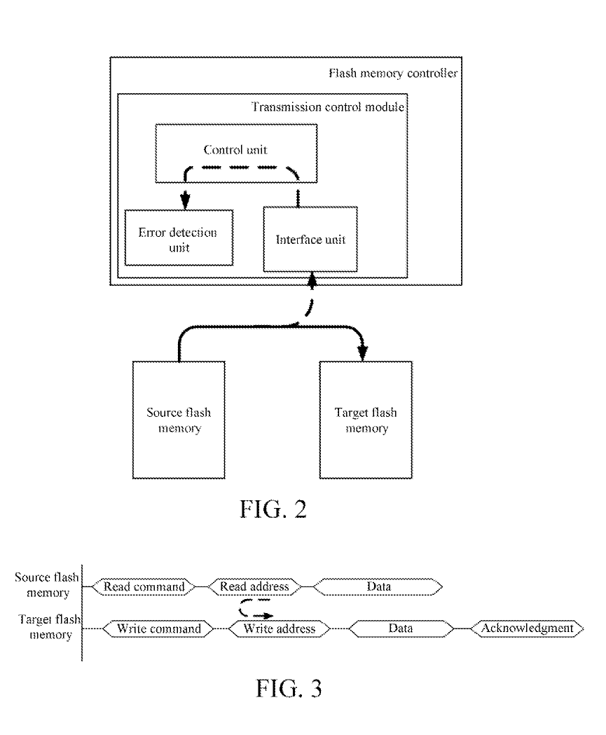

When data needs to be moved from a flash memory, that is, a source flash memory in a flash memory array to another flash memory, that is, a target flash memory in another flash memory array, the flow of data transmission is shown in FIG. 2. Under an operation of a control unit, data is read from the source flash memory, and is transmitted to the target flash memory and a flash memory controller through a data bus, respectively. In one aspect, the flash memory controller transmits the received data from an interface unit to an error detection unit to perform error detection. In another aspect, the data transmitted to the target flash memory is written in a buffer of the target flash memory. When acknowledging that no error occurs in the transmitted data, the error detection unit sends acknowledgment information to the control unit, and the transmitted data is written from the buffer to a storage unit of the target flash memory, so as to accomplish an entire operation of data transmission.

A flash memory sequence of the process of data transmission in this embodiment is shown in FIG. 3. Under the control of the control unit, the flash memory controller sends a read/write command to the source flash memory and the target flash memory, respectively, and transmits a read/write address. When the source flash memory and the target flash memory become ready, data read from the source flash memory is directly sent to the target flash memory, so as to reduce extra time overhead needed for the flash memory controller to perform storage and forwarding again in the process of reading data.

After the exchange of data is accomplished, the flash memory controller needs to perform error detection on the transmitted data to avoid error accumulation in the process of data exchange, and therefore the flash memory controller further uses a delayed acknowledgment manner after data transmission is accomplished to ensure correctness of the transmitted data. After the data transmission on the data bus is accomplished, the flash memory controller starts the error detection unit to perform error detection on the data. When no error occurs in the transmitted data, a acknowledgment command is sent, and the data is written from the buffer of the target flash memory to the storage unit of the target flash memory, so as to accomplish one process of data transmission.

Embodiment 2 is a correction processing process when an error occurs in data.

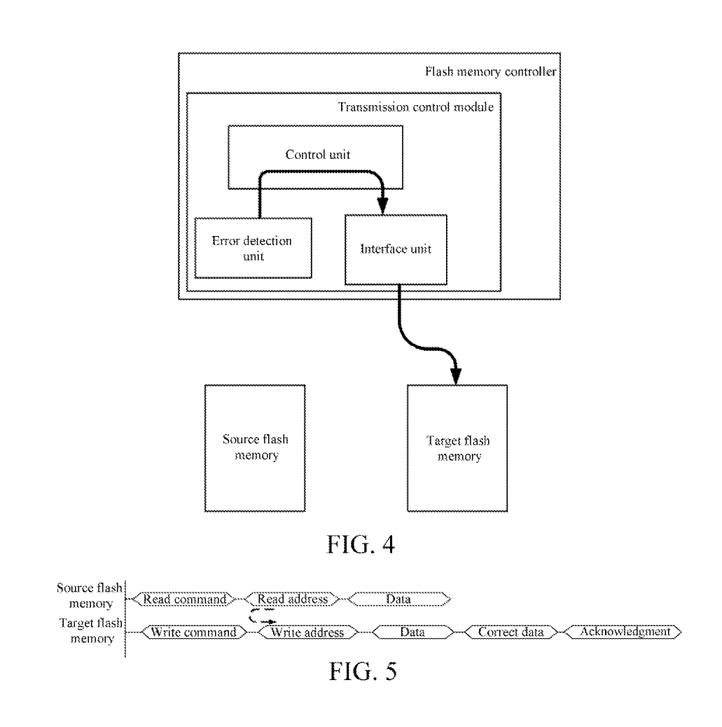

When an error occurs in transmitted data, a flash memory controller needs to perform corresponding correction processing, and a manner of data transmission is shown in FIG. 4. After an error detection unit discovers an error, the error detection unit may directly perform a correction operation on the data, and recover correct data through the correction operation. Next, the correct data is sent to an interface unit, and is sent to a buffer of a target flash memory again through the interface unit to overwrite data saved in a previous time of transmission.

A sequence diagram of performing the correction operation is shown in FIG. 5. After the data is transmitted in parallel, the correction operation is performed. After the correct data is obtained, the correct data is directly sent to the buffer of the target flash memory, so as to perform an update for original data sent when the data is transmitted in parallel. After an update operation is accomplished, a acknowledgment command is sent, so as to write the updated data in a storage unit of the target flash memory to accomplish an operation of data transmission.

The error detection unit performs correction processing in Embodiment 2. The error correction of the present invention may further have several implementation manners. For example, other functional units or an arranged new functional unit performs correction processing, as long as it is ensured that when an error occurs in data, correction processing is performed in time, corrected data is sent to the target flash memory to perform data update, and after the update is accomplished, the updated data in the buffer is further written in the storage unit of the target flash memory.

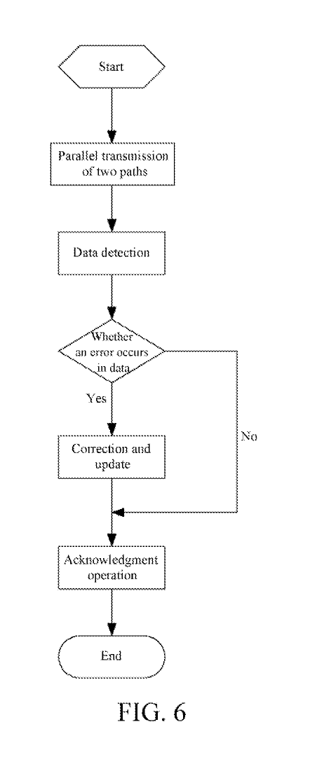

FIG. 6 shows a process of a method of data transmission between flash memories according to the present invention. After data transmission started, parallel data transmission in two paths is directly performed, and after data transmission is accomplished, error detection processing is performed on the data. Next, it is selected according to a result of the error detection processing whether to perform a data update operation. If no error is discovered in error processing, data transmission is acknowledged; if an error is discovered, correction processing is performed on erroneous data and an update is performed with the corrected data perform, and after the update is accomplished, data transmission is acknowledged, so that the updated is data written in the storage unit of the target flash memory, thereby accomplishing the operation of data transmission.

In conclusion, the flash memory controller proposed in the present invention can ensure correctness of transmitted data and also enhance a utilization rate of a bus in the process of transmitting data between the flash memories.

The foregoing content is further detailed illustration of the present invention with reference to specific implementation manners, and it should not be construed that the specific implementations of the present invention are only limited to the illustration. Therefore, a person of ordinary skill in the technical field of the present invention may further make several simple derivations or replacements without departing from the concept of the present invention, and these derivations or replacements should be construed as falling within the protection scope of the present invention.

What is claimed is:

1. A flash memory controller, comprising a transmission control module, wherein the transmission control module comprises: a control unit, an error detection unit, and an interface unit; the control unit is connected to the error detection unit and the interface unit, respectively, and is used to generate a read/write control instruction for data transmission between flash memories, the read/write control instruction comprises: a direct data transmission control instruction and a data error detection control instruction; the interface unit is further connected to a flash memory array, and is used to provide a data transmission interface to accomplish data transmission between the flash memory controller and the flash memory array; and the error detection unit is used to receive the data transmitted between the flash memories, and detect whether an error occurs in the data.

2. The flash memory controller according to claim 1, wherein the direct data transmission control instruction is used to control the data between the flash memories to be transmitted from a source flash memory to a target flash memory in the flash memory array; and the data error detection control instruction is used to control the data between the flash memories to be transmitted from the source flash memory in the flash memory array to the error detection unit through the interface unit.

3. The flash memory controller according to claim 1, wherein the interface unit is connected to the flash memory array through a data bus.

4. The flash memory controller according to claim 1, wherein the error detection unit is further used to perform correction processing on detected data in which an error occurs; and the read/write control instruction generated by the control unit further comprises: a corrected data control instruction.

5. The flash memory controller according to claim 4, wherein the corrected data control instruction is used to control the error detection unit to transmit the data after correction processing to the target flash memory in the flash memory array through the interface unit.

6. A method of data transmission between flash memories, comprising the following processing processes: reading data from a source flash memory in a flash memory array, and transmitting the data in the following two paths, respectively: one path being directly transmitting the data to a target flash memory in the flash memory array, and the other path being transmitting the data to an error detection unit through an interface unit; performing, by the error detection unit, error detection on the received data; storing, by the target flash memory, the received data in a buffer of the flash memory; and if a result of the error detection is that no error occurs in the data, writing the buffered data in a storage unit of the target flash memory.

7. The data transmission method according to claim 6, wherein the two paths of data are transmitted through a data bus.

8. The data transmission method according to claim 6, wherein the two paths of data are transmitted in parallel.

9. The data transmission method according to claim 6, wherein after the transmission of the two paths of data is accomplished, the error detection unit starts to perform error detection on the received data.

10. The data transmission method according to claim 6, wherein when the result of the error detection is that an error occurs in the data, after correction processing is performed on the data, the data is written in the storage unit of the target flash memory.

11. The data transmission method according to claim 10, wherein the correction processing is specifically: performing, by the error detection unit, correction processing on the data, and writing the corrected data in the storage unit of the target flash memory through the interface unit.

12. The data transmission method according to claim 10, wherein the writing the corrected data in the storage unit of the target flash memory comprises the following processing processes: writing the corrected data in a buffer unit of the target flash memory through the interface unit to perform a data update, and then writing the buffered data in the storage unit of the target flash memory.

13. The flash memory controller according to claim 2, wherein the error detection unit is further used to perform correction processing on detected data in which an error occurs; and the read/write control instruction generated by the control unit further comprises: a corrected data control instruction.

14. The flash memory controller according to claim 3, wherein the error detection unit is further used to perform correction processing on detected data in which an error occurs; and the read/write control instruction generated by the control unit further comprises: a corrected data control instruction.

15. The data transmission method according to claim 7, wherein when the result of the error detection is that an error occurs in the data, after correction processing is performed on the data, the data is written in the storage unit of the target flash memory.

16. The data transmission method according to claim 8, wherein when the result of the error detection is that an error occurs in the data, after correction processing is performed on the data, the data is written in the storage unit of the target flash memory.

17. The data transmission method according to claim 9, wherein when the result of the error detection is that an error occurs in the data, after correction processing is performed on the data, the data is written in the storage unit of the target flash memory.

18. The flash memory controller according to claim 13, wherein the corrected data control instruction is used to control the error detection unit to transmit the data after correction processing to the target flash memory in the flash memory array through the interface unit.

19. The flash memory controller according to claim 14, wherein the corrected data control instruction is used to control the error detection unit to transmit the data after correction processing to the target flash memory in the flash memory array through the interface unit.

20. The data transmission method according to claim 15, wherein the correction processing is specifically: performing, by the error detection unit, correction processing on the data, and writing the corrected data in the storage unit of the target flash memory through the interface unit.
